(19) United States
(12) Patent Application Publication
(10) Pub. No.: US 2016/0197546 A1
(43) Pub. Date: Jul. 7, 2016

(54) POWER DEVICE DRIVING MODULE AND POWER CONVERSION SYSTEM USING SAME

(71) Applicant: RUBY CO., LTD., Wanju (KR)

(72) Inventor: Eun-Ey JUNG, Paju (KR)

(21) Appl. No.: 14/909,486

(22) PCT Filed: Jul. 10, 2014
(86) PCT No.: PCT/KR2014/006202

§ 371 Date: Mar. 21, 2016

(30) Foreign Application Priority Data
Aug. 5, 2013 (KR) 10-2013-0092747
Mar. 20, 2014 (KR) 10-2014-0033019
Jul. 10, 2014 (KR) 10-2014-0086650

(51) Int. Cl. H02M 1/088; H03K 17/16

(52) U.S. Cl. CPC H02M 1/088; H03K 17/16; H02M 2001/0054

(57) ABSTRACT

An exemplary embodiment of the present invention provides a power device driving module. The power device driving module includes a module-processor configured to receive driving information from a central controller to generate a driving signal based on the driving information, and a driving circuit connected to a power device to switch the power device depending on the driving signal.

### TECHNICAL FIELD

The present invention relates to a power device driving module and a power conversion system using the same.

### BACKGROUND ART

A power conversion system (PCS) serving to perform power conversion by switching power devices may include, e.g., a DC/DC chopper, an AC/DC rectifier, a DC/AC inverter, and an AC/AC voltage controller. The power devices, which are switching devices used for power conversion, may include, e.g., an IGBT, an SCR, a BJT, and a MOSFET.

In the power conversion system, a central controller (mainboard) generates power device driving signals (e.g., PWM signals) by processing a power device driving algorithm or load feedback information, and transfers the driving signals to driving circuits of power devices. The power device driving circuits drive the corresponding power devices by using the driving signals transferred from the central controller. As such, this method of generating driving signals for all the power devices in the power conversion system by performing a batch process on all operations by the central controller may be referred to as a central power device driving method.

The central power device driving method has the advantage of being able to economically manage hardware and software. However, according to the central power device driving method, the load of signal processing is weighted in the central controller. Further, according to the central power device driving method, the PWM signals are vulnerable to noise due to long signal lines connected to the power devices, and lines such as feedback signal lines are connected to the central controller, thereby elongating and complicating a wiring system. Accordingly, the central power device driving method may cause system loads to increase and the system to malfunction due to the noise. In addition, according to the central power device driving method, since the central controller transfers the driving signals in a single direction, an additional wiring system is required to receive fault signals or feedback signals generated in the power devices.

### DISCLOSURE

### Technical Problem

The present invention has been made in an effort to provide a power device driving module and a power conversion system using the same, in which a power device driving signal is generated by each power device.

### Technical Solution

An exemplary embodiment of the present invention provides a power device driving module. The power device driving module includes a module-processor configured to receive driving information from a central controller to generate a driving signal based on the driving information, and a driving circuit connected to a power device to switch the power device depending on the driving signal.

The module-processor may generate a pulse width modulation (PWM) signal based on the driving information.

The power device driving module may further include a module-communicator configured to perform bidirectional communications with the central controller.

The power device driving module may further include a sensor connection terminal. The module-processor may receive sensing information from the sensor connection terminal and transfer the received sensing information to the central controller. The sensor connection terminal may be connected to a sensor disposed outside the power device driving module, and the sensor may include at least one of a current sensor, a voltage sensor, and a temperature sensor.

The power device driving module may further include a sensor unit configured to include at least one of a current sensor, a voltage sensor, and a temperature sensor. The module-processor may transfer sensing information received from the sensor to the central controller.

The module-processor may analyze an operational status of the power device, and may generate a driving signal of the power device based on an analysis result or transfer the analysis result to the central controller.

The driving circuit may include a first driving circuit configured to switch a first power device according to a first driving signal and a second driving circuit configured to switch a second power device according to a second driving signal. The module-processor may receive first driving information and second driving information from the central controller and respectively generate the first driving signal and the second driving signal based on the first driving information and the second driving information.

An exemplary embodiment of the present invention provides a power conversion system for converting power. The power conversion system includes a plurality of power device driving modules, and a central controller configured to transfer driving information related to generation of driving signals of at least one power device to the respective power device driving modules. Each of the power device driving modules may include a module-processor, one or more power devices and one or more driving circuits which are respectively connected to the power devices to drive the corresponding connected power devices. The module-processor may generate driving signals based on the driving information received from the central controller and switch the power devices depending on the driving signals.

The module-processor may generate a PWM signal based on the driving information.

Each of the power device driving modules may further include a module-communicator. The module-communicator may perform bidirectional communications with a central communicator of the central controller.

The module-processor may transfer sensing information sensed by at least one of a current sensor, a voltage sensor, and a temperature sensor to the central controller.

The module-processor may monitor operational statuses of the power devices and transfer monitored information to the central controller.

The central controller may set power devices of the power device driving modules to operate them as at least one of a first device for converting a DC power into a DC power, a second device for converting a DC power into an AC power, a third device for converting an AC power into a DC power, and a fourth device for converting an AC power into an AC power, and transfer driving information generated based on setting information to each of the power device driving modules.

### Advantageous Effects

According to the exemplary embodiments of the present invention, since a power device driving signal is generated by each power device, it is possible to reduce a data processing load of the mainboard. According to the exemplary embodiments of the present invention, a power device driving signal is directly generated by a power device, thereby obtaining a shortened wiring system. Accordingly, it is possible to provide a power conversion system that is strong against noise. According to the exemplary embodiments of the present invention, it is useful to manufacture a large-capacity power conversion system because it is simple to assemble the system. In addition, according to the exemplary embodiments of the present invention, since feedback signals of the power conversion system are processed by the power device, it is possible to eliminate a complex wiring system for connecting the feedback signals to the central controller.

### DESCRIPTION OF THE DRAWINGS

FIG. 1 and FIG. 2 are schematic diagrams illustrating a conventional power conversion system.

FIG. 3 and FIG. 4 are schematic diagrams illustrating a power conversion system according to an exemplary embodiment of the present invention.

FIG. 5, FIG. 6, and FIG. 7 are circuit diagrams illustrating a power device driving module according to an exemplary embodiment of the present invention.

### MODE FOR INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, unless explicitly described to the contrary, the word “comprise” and variations such as “comprises” or “comprising” will be understood to imply the inclusion of stated elements but not the exclusion of any other elements throughout this specification.

A power conversion system (PCS) includes power conversion devices for converting a first power into a second power, and may include, e.g., a DC/DC chopper, an AC/DC rectifier, a DC/AC inverter, and an AC/AC voltage controller. The power conversion system may be disposed between a power source (or grid) and a load (or grid) to convert power from a power source depending on the load.

A power device includes transistor devices that are switched according to driving signals, and may include, e.g., a silicon controlled rectifier (SCR), a bipolar junction transistor (BJT), a metal oxide silicon field effect transistor (MOSFET), and an insulated gate bipolar mode transistor (IGBT).

A power device driving module and a power conversion system using the same according to an exemplary embodiment of the present invention will now be described in detail with reference to related drawings.

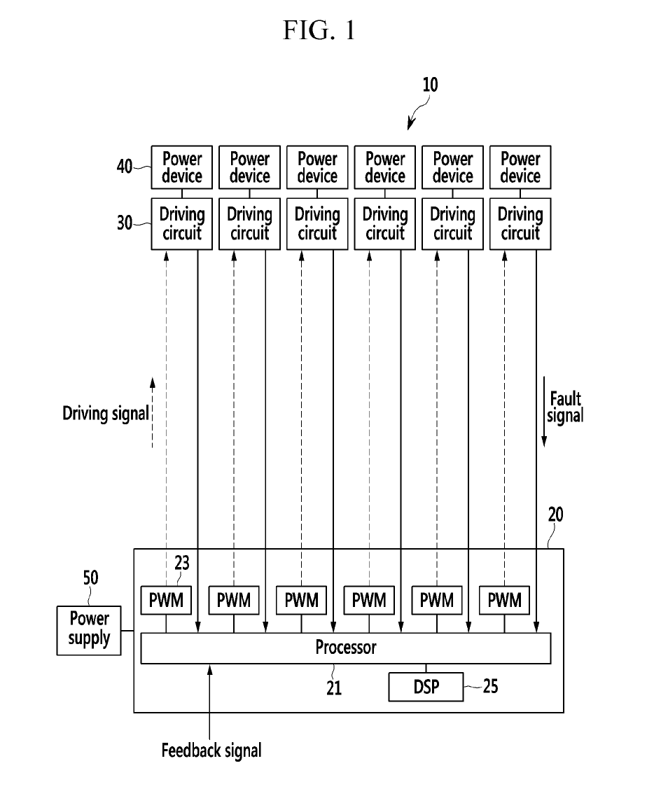

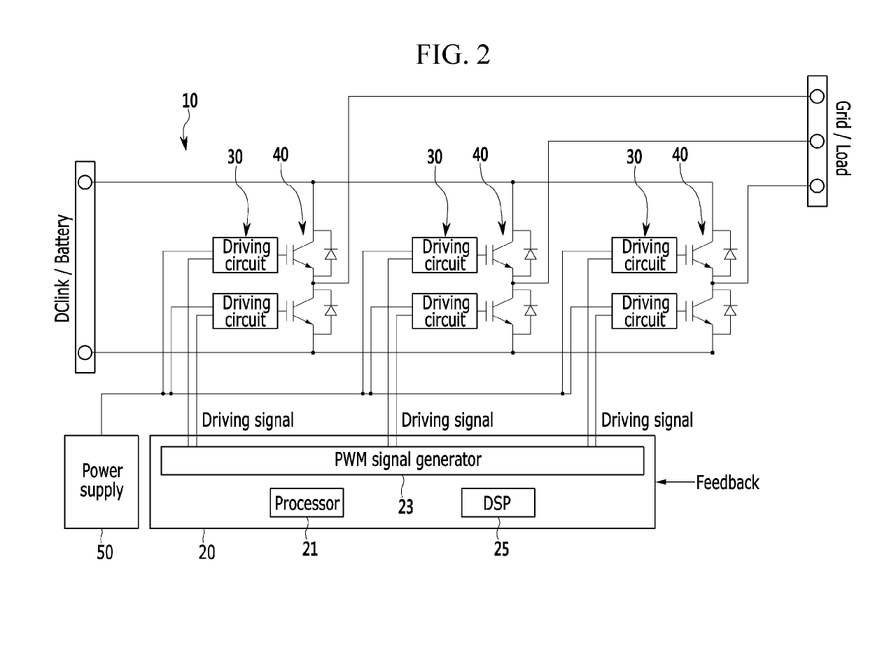

FIG. 1 and FIG. 2 are schematic diagrams illustrating a conventional power conversion system.

Referring FIG. 1 and FIG. 2, the conventional power conversion system 10 includes a central controller 20, a plurality of power device driving circuits 30, a plurality of power devices 40, and a power supply device 50.

The central controller 20 includes a processor 21, PWM (pulse width modulation) signal generators 23, and a digital signal processor (DSP) 25. The PWM signal generators 23 are connected to the power device driving circuits 30 one by one. The power supply device 50 supplies powers to the respective power device driving circuits 30.

The central controller 20 generates driving signals (PWM signals) for the respective power devices 40 based on power device driving algorithms or load feedback information. In this case, the PWM signal generators 23 transfer the driving signals through single-directional connection lines. As such, the central controller 20 generates a 5 V driving signal (logic power control signal) to directly turn a power device on or off, for example.

The power device driving circuits 30 are connected to the power devices 40. The power device driving circuits 30 drive the power devices 40 depending on the driving signals.

The power device driving circuits 30 transfer fault signals of the power devices 40 to the central controller 20. In this case, the power device driving circuits 30 transfer the fault signals through connection lines other than those of the driving signals.

The central controller 20 feeds back power information of loads and performs an A/D (analog to digital) conversion on it. The central controller 20 newly generates driving signals for the power devices based on the feedback information transferred from the loads or the power device driving circuits 30, and transfers them to power device driving modules.

As such, in the power conversion system 10, the central controller 20 processes all operations to generate driving signals for all the power devices thereof. Accordingly, in the power conversion system 10, as the number of power devices is increased, a signal processing load of the central controller 20 is weighted. The power conversion system 10 may have a complex wiring system, and a noise thereof may be increased in proportion to a transferring length of driving signals, thereby malfunctioning. Further, since the power conversion system 10 transfers the driving signals in a single direction, an additional wiring system is required for the central controller 20 to receive feedback signals such as fault signals generated in the power devices. In addition, it is difficult for the central controller 20 to check in real time whether the driving signals are transferred to the power devices.

Next, exemplary embodiments of the present invention for solving problems of the power conversion system 10 will be described.

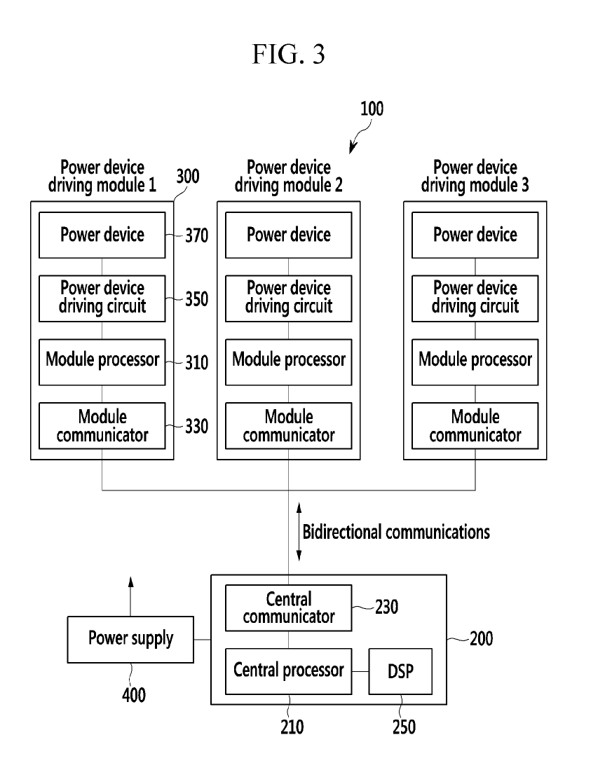

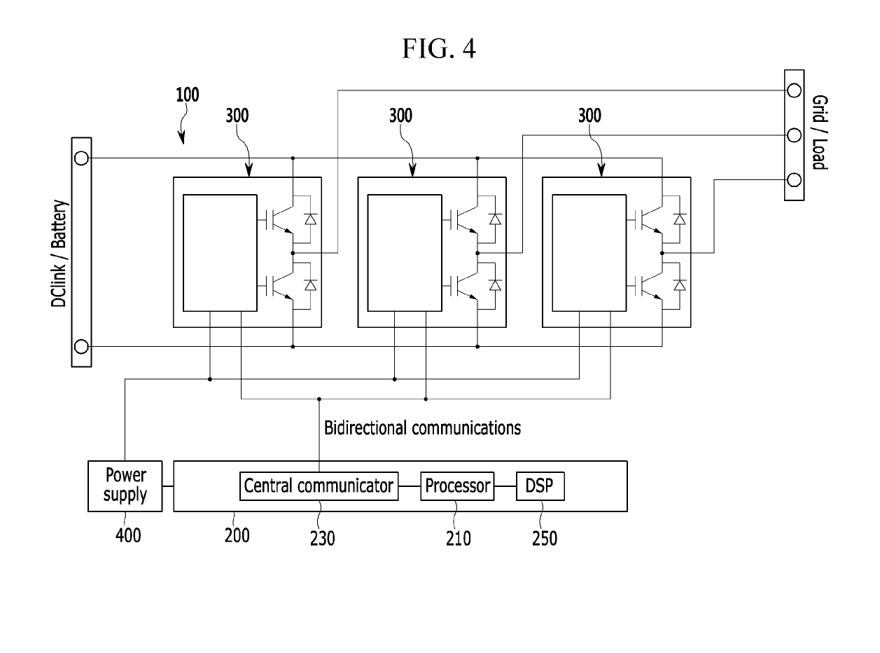

FIG. 3 and FIG. 4 are schematic diagrams illustrating a power conversion system according to an exemplary embodiment of the present invention.

Referring to FIG. 3 and FIG. 4, the power conversion system 100 may be disposed between a power source (or grid) and a load (or grid) to perform power conversion. According to the present exemplary embodiment, the power conversion system 100 may serve as a DC/AC inverter including an AC/DC rectifier and a DClink/battery. Power devices may serve as an AC/DC rectifier, a DC/AC inverter, or a bidirectional DC/AC converter depending on driving signals.

The power conversion system 100 includes a central controller 200, a plurality of power device driving modules 300, and a power supply device 400. The power supply device 400 supplies powers to the respective power device driving modules 300.

The central controller 200 includes a central processor 210, a central communicator 230, and a digital signal processor (DSP) 250.

Each of the power device driving modules 300 includes a module-processor 310, a module-communicator 330, a power device driving circuit 350, and a power device 370. The power device driving module 300 may include a plurality of power device driving circuits 350 and a plurality of power devices 370. The module-processor 310 includes a PWM signal generator, an analog-digital converter (ADC), a general purpose input/output (GPIO), and the like. The driving signals may be variously embodied depending on the driving circuits or the power devices. Herein, PWM signals are taken as an example.

The central communicator 230 is connected with N module-communicators 330 in the proportion of 1 to N. The central communicator 230 and the N module-communicators 330 perform bidirectional communications with each other. In this case, the central communicator 230 and the N module-communicators 330 may be embodied as various communication modules to support, e.g., controller area network (CAN) communication, RS485 communication, and RS422 communication. Copper lines may be employed for a wiring system. Further, optical cables may be employed when communication modules are embodied as optical modules.

The central controller 200 executes a power device control algorithm to operate the power conversion system 100 as a rectifier, inverter, or a bidirectional DC/AC converter. Specifically, the central controller 200 manages control algorithms for each power device as a device for converting a DC power into a DC power, a device for converting a DC power into an AC power, a device for converting an AC power into a DC power, or a device for converting an AC power into an AC power. Further, the central controller 200 transfers various kinds of driving information related to driving signal generation to each power device driving module depending on the control algorithms. The driving information includes power device driving module ID information, switching variables, and the like. The driving information is transferred to the module-communicator 330 through the central communicator 230.

The central controller 200 transfers data frames including switching variables required to generate driving signals of power device driving modules. The switching variables may include information that is required for various types of switching of, e.g., pulse widths as information that is required to generate driving signals (PWM signals). In other words, the central controller 200 transfers information that is required to generate a driving signal (PWM signal) in the power device driving module 300 instead of transferring the driving signal to the power device driving module 300.

The module-processor 310 of the power device driving module 300 generates the driving signal (PWM signal) based on the driving information. The module-processor 310 generates a driving signal for a corresponding power device by creating, e.g., a duty ratio of a switching pulse based on the driving information.

The power device driving circuit 350 drives a power device 370 based on a PWM signal generated in a module-processor 310.

The module-processor 310 can recognize statuses of the power devices in real time. The module-processor 310 may transfer data frames including operational information, status information, and the like of the power devices to the central controller 200.

The module-processor 310 collects sensing information from various sensors such as a voltage sensor and a current sensor of the power conversion system 100, and generates a PWM signal based on the sensing information or transfers the sensing information to the central processor 210. For example, the module-processor 310 may monitor current, voltage, temperature, and the like instead of the central processor 210, and may control the power device based on monitored information. In this case, the sensors are connected to the module-processor 310. Accordingly, a simple sensor connection wiring system is obtained as compared with the conventional power conversion system 10.

As a next step, the module-processor 310 analyzes an operational status of the power device without using an additional current sensor or voltage sensor, and drives the power device 370 based on analyzed results. Alternatively, the module-processor 310 may transfer the results of analyzing the power device to the central processor 210. The central processor 210 can organically manage the power device driving modules by synthesizing status information of the power device received from the module-processors 310. As a result, the power conversion system 100 can obtain information that can be conventionally obtained by necessarily using an additional sensor such as a current sensor, from the module-processors 310. Therefore, the power conversion system 100 can serve as a sensor-less PCS.

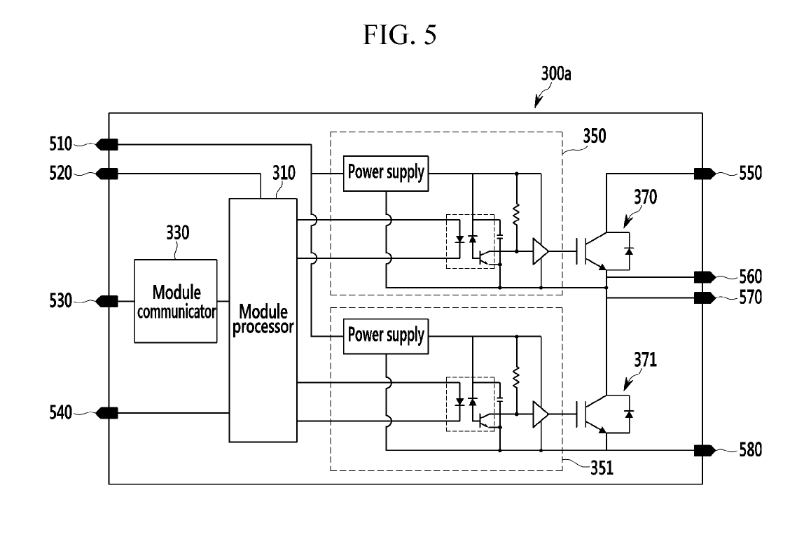

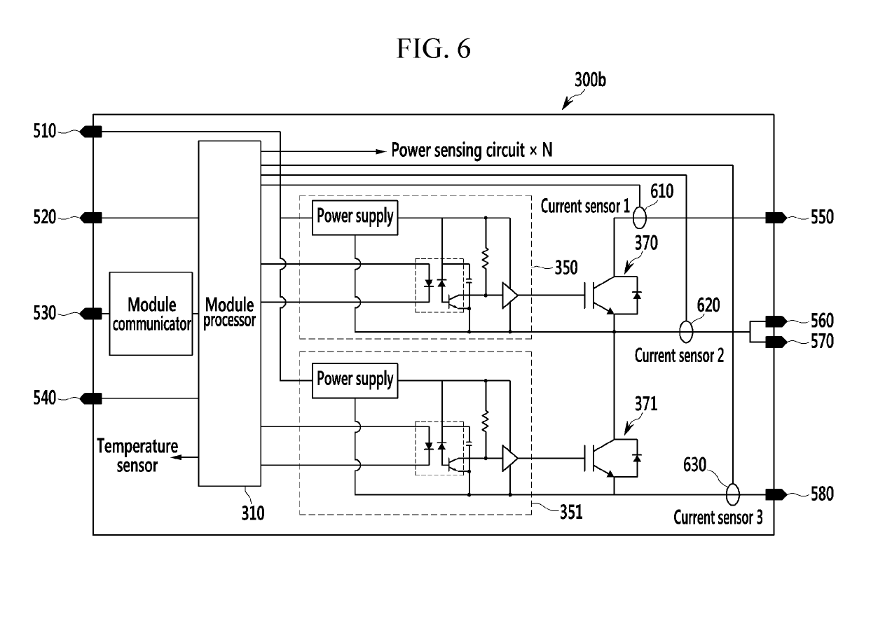

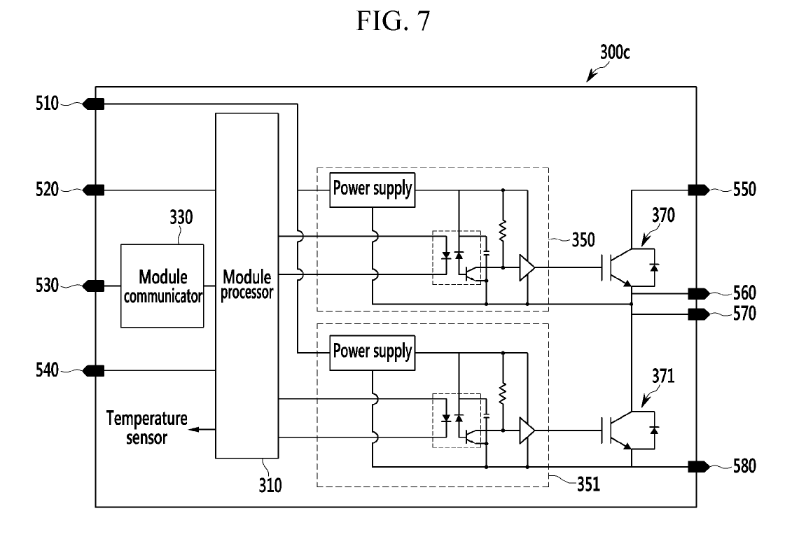

FIG. 5 to FIG. 7 are circuit diagrams illustrating a power device driving module according to an exemplary embodiment of the present invention.

Referring to FIG. 5 to FIG. 7, the power device driving module 300a may include at least one power device driving circuit 350 and at least one power device 370. Hereinafter, an example in which the power device driving module 300 includes two power devices 370 and 371 will be described.

First, referring to FIG. 5, the power device driving module 300a includes a module-processor 310, a module-communicator 330, power device driving circuits 350 and 351, and the power devices 370 and 371. The power device driving circuits 350 and 351 include a power supply for supplying power that is required for circuit operation. The power supply may be an isolated DC power supply.

The power device driving module 300a includes a plurality of connection terminals for external connection, such as power source connection terminals 510 and 520, a communication connection terminal 530, a sensor connection terminal 540, and power device connection terminals 550, 560, 570, and 580.

The power source connection terminal 510 is connected to an external power supply device 400. The power source connection terminal 510 is connected to the power supply of the power device driving circuits 350 and 351 to supply power that is required for the power devices. The power source connection terminal 520 is connected to the module-processor 310 to supply power.

The communication connection terminal 530 is connected to the central communicator 230 which is disposed at the outside. The communication connection terminal 530 is connected to the module-communicator 330.

The sensor connection terminal 540 is connected to at least one external sensor or a control line. The sensor connection terminal 540 is connected to the module-processor 310 to transfer external sensor information to the module-processor 310.

The power device connection terminals 550, 560, 570, and 580 are connected to corresponding electrodes of the power devices.

The power device driving circuits 350 and 351 respectively switch the power devices 370 and 371 depending on the driving signals (PWM signals) transferred from the module-processor 310. The power device driving circuits 350 and 351 may be variously designed.

The module-communicator 330 performs the bidirectional communications with the central communicator 230 of the power conversion system 100. The module-communicator 330 receives various kinds of driving information related to driving signal generation of the corresponding power device from the central controller 200 or transfers the various kinds of driving information to the central controller 200, by using the bidirectional communications. For example, the driving information includes power device driving module ID information, switching variables, various kinds of feedback information, and the like. The module-communicator 330 may be embodied as a module capable of bidirectional communications. For example, the module-communicator 330 may be embodied as a communication module capable of CAN communications, RS485 communications, RS422 communications, or the like. Copper lines or optical cables may be employed as communication media.

The module-processor 310 includes a PWM signal generator, an ADC, a GPIO, and the like. The module-processor 310 generates driving signals (PWM signals) for the power devices 370 and 371 based on the driving information transferred from the module-communicator 330. The module-processor 310 generates the driving signals (PWM signals) for the power devices based on the driving information, i.e., switching variables from the central controller 200.

The driving signals generated in the module-processor 310 are transferred to the power device driving circuit. In other words, the local module-processor 310 individually generates the driving signals to directly turn the power devices 370 and 371 on or off instead of allowing the central controller 200 of the power conversion system 100 to generate the driving signals for the power devices 370 and 371.

The module-processor 310 may actively control the power devices 370 and 371 to control the power devices 370 and 371 to serve as a DC/DC chopper, an AC/DC rectifier, a DC/AC inverter, an AC/AC voltage controller, and the like.

The module-processor 310 collects external sensor information or control information through the sensor connection terminal 540. For example, the external sensor may be a voltage sensor, a current sensor, a temperature sensor, a fuse sensor, or the like. The control information may be fan control information or MC (magnetic contact switch) control information. The module-processor 310 controls the power devices 370 and 371 based on the external sensor information. In other words, the module-processor 310 locally analyzes operational statuses of the power devices 370 and 371 to generate signals for controlling the power devices 370 and 371.

The module-processor 310 performs the bidirectional communications with the central controller 200 through the module-communicator 330. The module-processor 310 may collect driving information and system information and may transfer status information of the power device driving modules and the power devices to the central controller 200, and thus the central controller 200 may use the transferred information as feedback information.

As such, the power device driving module 300a includes processors to independently execute algorithms for switching statuses, safety, and protection of the power devices. Further, the power device driving module 300a can transfer necessary information to the central controller 200 to enable the central controller 200 to perform smart power management.

Referring to FIG. 6, a power device driving module 300b is similar to the power device driving module 300a. However, a circuit for processing various types of signals is mounted in the power device driving module 300b. The power device driving module 300b may include at least one of a voltage sensor, a current sensor, and a temperature sensor. For example, current sensors 610, 620, and 630 may be attached to a collector of a power device 370, a line (bus bar) connecting an emitter of the power device 370 with a collector of a power device 371, and an emitter of the power device 371.

The current sensors 610, 620, and 630 may be connected to the module-processor 310, and thus the module-processor 310 may process sensing information of the current sensors 610, 620, and 630. A plurality of voltage sensing circuits may be connected to the module-processor 310, and thus the module-processor 310 may process sensing information of the voltage sensing circuits.

For example, the sensors may be connected to the power device driving module 300b by using connectors. Alternatively, all or some of the sensors may be mounted in the power device driving module 300b.

The sensors sense currents flowing in the power devices and transfer sensing information to the module-processor 310. The module-processor 310 may locally analyze the sensing information sensed by the current sensors by itself, or may transfer it to the central controller 200. The central controller 200 generates driving information based on sensing information.

Referring to FIG. 7, a power device driving module 300c is similar to the power device driving module 300a or 300b. However, the power device driving module 300c does not collect sensor information from a separate internal or external sensor.

The power device driving module 300c does not include separate voltage and current sensors, and the module-processor 310 analyzes operational statuses such as voltage variations, current variations, and temperature variations of the power devices. The power device driving module 300c generates signals for driving the power devices based on analysis data, or may transfer the analysis data to the central controller 200. The central controller 200 receives analysis information related to operational statuses of the power devices transferred from the power device driving modules instead of obtaining various kinds of feedback information from the current sensor or the voltage sensor. The central controller 200 may generate switching variables of the power devices by using the information received from the power devices. Alternatively, the power device driving module 300c may directly generate the driving signals of the power devices by analyzing the operational statuses of the power devices by itself.

As a result, the central controller 200 or the power device driving module 300c realizes a sensor-less PCS by generating power device driving signals without using a separate voltage or current sensor.

As such, according to the exemplary embodiments of the present invention, since a power device driving signal is generated by each power device, it is possible to reduce a data processing load of the mainboard. According to the exemplary embodiments of the present invention, it is possible to provide a power conversion system that is strong against noise by using a shortened wiring system. According to the exemplary embodiments of the present invention, it is useful to manufacture a large-capacity power conversion system because it is simple to assemble the system.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A power device driving module comprising:
a module-processor configured to receive driving information from a central controller to generate a driving signal based on the driving information; and
a driving circuit connected to a power device to switch the power device depending on the driving signal.

2. The power device driving module of claim 1, wherein the module-processor generates a pulse width modulation (PWM) signal based on the driving information.

3. The power device driving module of claim 1, further comprising
a module-communicator configured to perform bidirectional communications with the central controller.

4. The power device driving module of claim 1, further comprising
a sensor connection terminal,
wherein the module-processor receives sensing information from the sensor connection terminal, and transfers the received sensing information to the central controller, and
the sensor connection terminal is connected to a sensor disposed outside the power device driving module, and the sensor includes at least one of a current sensor, a voltage sensor, and a temperature sensor.

5. The power device driving module of claim 1, further comprising
a sensor unit configured to include at least one of a current sensor, a voltage sensor, and a temperature sensor,
wherein the module-processor transfers sensing information received from the sensor to the central controller.

6. The power device driving module of claim 1, wherein the module-processor analyzes an operational status of the power device, and generates a driving signal of the power device based on an analysis result or transfers the analysis result to the central controller.

7. The power device driving module of claim 1, wherein the driving circuit includes a first driving circuit configured to switch a first power device according to a first driving signal and a second driving circuit configured to switch a second power device according to a second driving signal,
wherein the module-processor receives first driving information and second driving information from the central controller, and respectively generates the first driving signal and the second driving signal based on the first driving information and the second driving information.

8. A power conversion system for converting power, the system comprising:
a plurality of power devices driving modules; and
a central controller configured to transfer driving information related to generation of driving signals of at least one power device to the respective power device driving modules,
wherein each of the power device driving modules includes a module-processor, one or more power devices, and one or more driving circuits which are respectively connected to the power devices to drive the corresponding connected power devices, and
wherein the module-processor generates driving signals based on the driving information received from the central controller and switches the power devices depending on the driving signals.

9. The power conversion system of claim 8, wherein the module-processor generates a PWM signal based on the driving information.

10. The power conversion system of claim 8, wherein each of the power device driving modules further includes a module-communicator,
wherein the module-communicator performs bidirectional communications with a central communicator of the central controller.

11. The power conversion system of claim 8, wherein the module-processor transfers sensing information sensed by at least one of a current sensor, a voltage sensor, and a temperature sensor to the central controller.

12. The power conversion system of claim 8, wherein the module-processor monitors operational statuses of the power devices, and transfers monitored information to the central controller.

13. The power conversion system of claim 8, wherein the central controller sets the power devices of the power device driving modules to operate them as at least one of a first device for converting a DC power into a DC power, a second device for converting a DC power into an AC power, a third device for converting an AC power into a DC power, and a fourth device for converting an AC power into an AC power, and transfers driving information generated based on setting information to each of the power device driving modules.
